(19) United States
(12) Patent Application Publication
(10) Pub. No.: US 2026/0059987 A1
(43) Pub. Date: Feb. 26, 2026

(54) Display Apparatus

(71) Applicant: LG Display Co., Ltd., Seoul (KR)

(72) Inventors: Seongku Lee, Paju-si (KR); MunChae Yoon, Paju-si (KR); Seungyeop Lee, Paju-si (KR)

(21) Appl. No.: 19/234,688

(22) Filed: Jun. 11, 2025

(30) Foreign Application Priority Data
Aug. 21, 2024 (KR) 10-2024-0112355

(51) Int. Cl. H10K 59/80; H10K 59/121; H10K 59/122; H10K 59/131; H10K 59/38; H10K 102/00

(52) U.S. Cl. CPC H10K 59/8791; H10K 59/1216; H10K 59/122; H10K 59/131; H10K 59/38; H10K 59/80515; H10K 2102/351

(57) ABSTRACT

A display apparatus comprising: a substrate having a plurality of pixels having a plurality of subpixels, a light-emitting element layer disposed on the substrate and included in each of the plurality of subpixels, a color filter layer between the light-emitting element layer and the substrate, a first layer between the color filter layer and the substrate, and a second layer covering at least a portion of the first layer between the first layer and the color filter layer, wherein the first layer is a transparent layer and the second layer is an opaque layer.

### CROSS-REFERENCE TO RELATED APPLICATIONS

This application claims the benefit of the Korean Patent Applications No. 10-2024-0112355 filed on Aug. 21, 2024, which is hereby incorporated by reference in its entirety.

### BACKGROUND

### Field of Technology

The present disclosure relates to a display apparatus displaying images.

### Discussion of the Related Art

Since an organic light emitting display apparatus has a high response speed and low power consumption and self-emits light without requiring a separate light source unlike a liquid crystal display apparatus, there is no problem in a viewing angle. Thus, the organic light emitting display apparatus has received attention as a next-generation flat panel display apparatus.

Such a display apparatus displays an image through light emission from a light-emitting element layer including a light-emitting layer interposed between a pixel electrode and an opposing electrode.

Meanwhile, the display apparatus additionally provides a transparent electrode under the pixel electrode in an opening to reduce an area of the circuit area, and uses the pixel electrode and the transparent electrode as a capacitor. Accordingly, the display apparatus is equipped with a structure in which the transparent electrode, a color filter, the pixel electrode, and the opposing electrode are sequentially laminated on a substrate. However, the display apparatus has a problem in that the visibility of the image is reduced because a reflectance of external light reflected by the opposing electrode is high due to the color filter and the transparent electrode located under the opposing electrode.

### SUMMARY

An embodiment of the present disclosure is directed to provide a display apparatus with reduced external light reflectance.

Further, an embodiment of the present disclosure is directed to providing a display apparatus with improved image visibility.

Further, an embodiment of the present disclosure is directed to providing a display apparatus in which power consumption can be reduced by reducing external light reflectance.

The problems to be solved by the examples of the present disclosure are not limited to those mentioned above, and other problems not mentioned will be apparent to one of ordinary skill in the art to which the technical spirits of the present disclosure belong from the following description.

A display apparatus comprising: a substrate having a plurality of pixels having a plurality of subpixels, a light-emitting element layer disposed on the substrate and included in each of the plurality of subpixels, a color filter layer between the light-emitting element layer and the substrate, a first layer between the color filter layer and the substrate, and a second layer covering at least a portion of the first layer between the first layer and the color filter layer, wherein the first layer is a transparent layer and the second layer is an opaque layer.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

In the drawings:

FIG. 1 is a schematic plan view of a display apparatus according to one embodiment of the present disclosure.

FIG. 2 is a schematic plan view of one pixel illustrated in FIG. 1 according to one embodiment of the present disclosure.

FIG. 3 is a schematic cross-sectional view of the line I-I′ shown in FIG. 2 according to one embodiment of the present disclosure.

FIG. 4 is a schematic cross-sectional view of a display apparatus according to a second embodiment of the present disclosure.

FIG. 5 is a schematic cross-sectional view of a display apparatus according to a third embodiment of the present disclosure.

FIG. 6 is a plan view showing one example of a second layer arranged in a light emission area of a display apparatus according to one embodiment of the present disclosure.

FIG. 7 is a plan view showing a second example of a second layer arranged in a light emission area of a display apparatus according to one embodiment of the present disclosure.

FIG. 8 is a plan view showing a third example of a second layer arranged in a light emission area of a display apparatus according to one embodiment of the present disclosure.

FIG. 9 is a plan view showing a fourth example of a second layer arranged in a light emission area of a display apparatus according to one embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely one example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct”is used.

It will be understood that, although the terms “first,” “second,” etc. may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the various embodiments of the present disclosure will be described in detail with reference to the accompanying drawings.

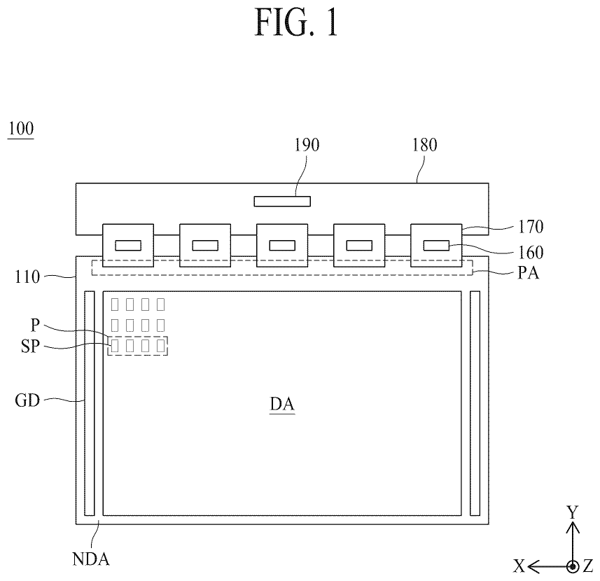

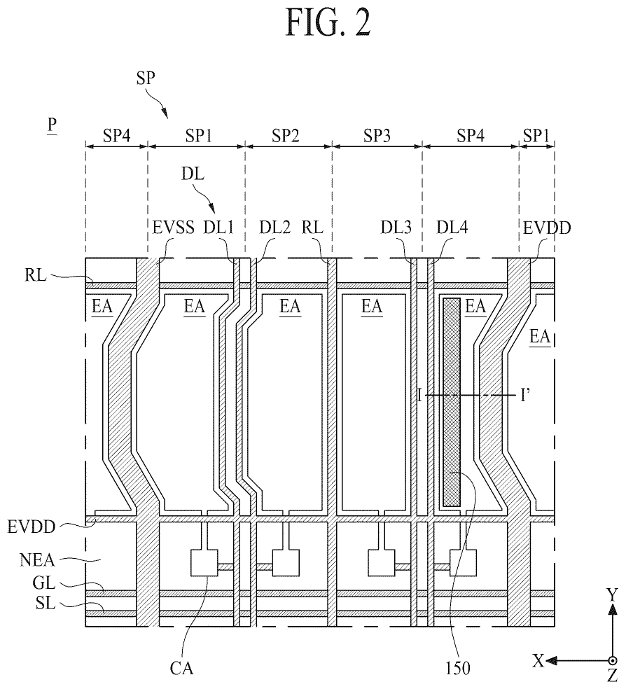

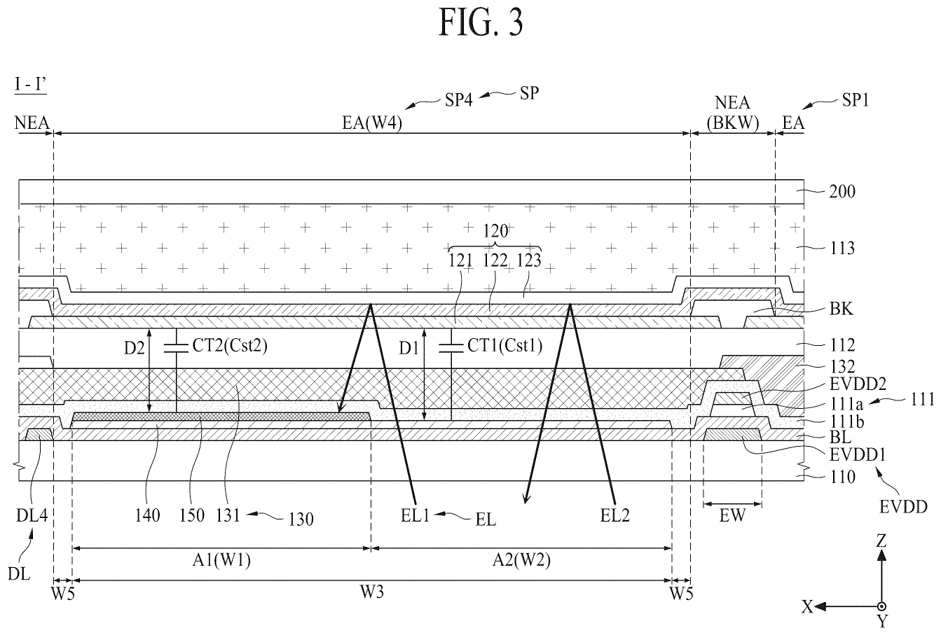

FIG. 1 is a schematic plan view of a display apparatus according to one embodiment of the present disclosure, FIG. 2 is a schematic plan view of one pixel illustrated in FIG. 1 according to one embodiment of the present disclosure, and FIG. 3 is a schematic cross-sectional view of the line I-I′ shown in FIG. 2 according to one embodiment of the present disclosure.

Hereinafter, a first direction (Y-axis direction) indicates a direction parallel to the data line DL, a second direction (X-axis direction) indicates a direction parallel to a gate line GL, and a third direction (Z-axis direction) indicates a thickness direction of the display apparatus 100.

The following description will be based on that the display apparatus 100 according to one embodiment of the present disclosure is an organic light emitting display apparatus, but is not limited thereto. That is, the display apparatus according to one embodiment of the present disclosure may be implemented as any one of a liquid crystal display apparatus, a field emission display apparatus, a quantum dot lighting emitting diode apparatus, and an electrophoretic display apparatus as well as the organic light emitting display apparatus.

Referring to FIG. 1, the display apparatus 100 according to one embodiment of the present disclosure may include a display panel having a gate driver GD. The display panel may include a substrate 110 and an opposite substrate 200 (shown in FIG. 3), which are bonded to each other. The substrate 110 according to one example may include a plurality of pixels P having a plurality of subpixels SP. As shown in FIG. 3, the display apparatus 100 according to one embodiment of the present disclosure may further include a light emitting element layer 120, a color filter layer 130, a first layer 140, and a second layer 150 disposed on the substrate 110. The first layer 140 according to one example may be a transparent layer (or a transparent film). The second layer 150 according to one example may be an opaque layer (or an opaque film). The display apparatus 100 according to one embodiment of the present disclosure can have a reduced external light reflectance by having the second layer 150 disposed on the first layer 140 to cover at least a portion of the first layer 140. A specific description thereof will be provided after describing the overall structure of the display apparatus 100 according to one embodiment of the present disclosure.

Referring to FIG. 1, the display apparatus 100 according to one embodiment of the present disclosure may further include a source drive integrated circuit (hereinafter, referred to as “IC”) 160, a flexible film 170, a circuit board 180, and a timing controller 190. Embodiments are not limited thereto. As an example, one or more above-mentioned components may be omitted, and/or one or more additional components may be further included.

The substrate 110 may include a thin film transistor, and may be a transistor array substrate, a lower substrate, a base substrate, or a first substrate. The substrate 110 may be a transparent glass substrate or a transparent plastic substrate. Embodiments are not limited thereto. As an example, the substrate 110 may be an opaque substrate. As an example, the substrate 110 may be a flexible substrate or a rigid substrate. As an example, the substrate 110 may comprise glass, plastic, a metal foil, inorganic nonmetallic materials or a flexible polymer film including polyethylene terephthalate (PET), polycarbonate (PC), etc.

The opposite substrate 200 may be bonded to the substrate 110 via an adhesive member. For example, the opposing substrate 200 has a smaller size than the substrate 110 and can be bonded to the remaining portion of the substrate 110 except for the pad portion, without being limited thereto. The opposite substrate 200 may be an upper substrate, a second substrate, or an encapsulation substrate.

The gate driver GD supplies gate signals to the gate lines in accordance with the gate control signal input from the timing controller 190. When the source drive IC 160 is manufactured as a driving chip, the source drive IC 160 may be packaged in the flexible film 170 in a chip on film (COF) method or a chip on plastic (COP) method.

Pads such as power pads and data pads may be formed in a non-display area of a display panel. A flexible film 170 may include lines connecting the pads to a source drive IC 160 and lines connecting the pads to lines of a circuit board 180. The flexible film 170 may be attached to the pads by using an anisotropic conducting film, whereby the pads may be connected to the lines of the flexible film 170, without being limited thereto.

Referring to FIG. 1, the substrate 110 according to one example may include a display area DA and a non-display area NDA. As an example, the non-display area NDA may be extended from the display area DA. As an example, the non-display area NDA may fully or partially surround the display area DA. As an example, the non-display area NDA may be at least partially invisible from a front side of the substrate 110 by being bent toward a rear side of the substrate 110, without being limited thereto.

The display area DA is an area where an image is displayed, and may be a pixel array area, an active area, a pixel array unit, a display unit, or a screen. For example, the display area DA may be disposed at a central portion of the display panel, or may be biased from the central portion of the display panel.

The display area DA according to one example may include gate lines, data lines, pixel power lines, and a plurality of pixels P. Each of the plurality of pixels P may include a plurality of sub-pixels SP that may be defined by the gate lines and the data lines. Each of the plurality of sub-pixels SP may be defined as a minimum unit area in which light is actually emitted.

According to one example, at least four sub-pixels, which are provided to emit light of different colors and disposed to be adjacent to one another, among the plurality of sub-pixels SP constitute one unit pixel P. One unit pixel may include, but is not limited to, a red sub-pixel, a green sub-pixel, a blue sub-pixel, a white sub-pixel. According to another example, three sub-pixels SP, which are provided to emit light of different colors and disposed to be adjacent to one another, among the plurality of sub-pixels SP constitute one unit pixel. One unit pixel may include at least one red sub-pixel, at least one green sub-pixel, at least one blue sub-pixel, but is not limited thereto. Embodiments are not limited thereto. As an example, one unit pixel may include two or more subpixels. As an example, the two or more subpixels included in one unit pixel may emit light of different color, or at least two of the subpixels included in one unit pixel may emit light of the same color, without being limited thereto. As an example, a sub-pixel emitting light of a color other than red, green, blue and white may be alternatively or additionally include.

Each of the plurality of sub-pixels SP may include a thin film transistor and a light emitting element connected to the thin film transistor. The sub-pixel may include a light emitting layer (or an organic light emitting layer) interposed between a first electrode and a second electrode.

The organic light emitting layer disposed in each of the plurality of sub-pixels SP may individually emit light of different colors or may commonly emit white light. According to one example, when the organic light emitting layer of each of the plurality of sub-pixels SP commonly emits white light, each of the red sub-pixel, the green sub-pixel and the blue sub-pixel may include a color filter (or a wavelength conversion member) for converting the white light into light of different colors. In this case, the white sub-pixel according to one example may not include a color filter, without being limited thereto. The color filter 130, according to one example, can include a green color filter 131 (shown in FIG. 3), a red color filter 132 (shown in FIG. 3), and a blue color filter. As an example, a color filter of other colors may be alternatively or additionally included.

In the display apparatus 100 according to one embodiment of the present disclosure, an area in which a red color filter 132 is provided may be a red sub-pixel SP1, an area in which a blue color filter is provided may be a blue sub-pixel SP3, an area in which a green color filter 131 is provided may be a green sub-pixel SP4, and an area in which a color filter is not provided may be a white sub-pixel SP2. In the present disclosure, the red sub-pixel SP1 may be expressed as a first sub-pixel provided to emit red light, the blue sub-pixel SP3 may be expressed as a third sub-pixel configured to emit blue light, the green sub-pixel SP4 may be expressed as a fourth sub-pixel provided to emit green light, and the white sub-pixel SP2 may be represented as a second sub-pixel provided to emit white light.

Each of the plurality of sub-pixels SP supplies a predetermined current to the organic light emitting element in accordance with a data voltage of the data line when a gate signal is input from the gate line by using the thin film transistor. For this reason, the light emitting layer of each of the sub-pixels may emit light with a predetermined brightness in accordance with the predetermined current.

As shown in FIG. 2, the display area DA includes a light emission area EA and a non-light emission area NEA. The light emission area EA is an area where light is emitted by a light emitting element layer 120 (shown in FIG. 3). The non-light emission area NEA is an area where no light is emitted. For example, the non-light emission area NEA can be an area other than the light emission area EA from which light is emitted. In one example, the non-light emission area NEA can be provided on the substrate 110 between the plurality of sub-pixels SP. A circuit area CA for emitting light from the light-emitting element layer 120 may be placed in the non-light emission area NEA. As shown in FIG. 2, the circuit area CA according to one example may be placed below the light-emission area EA. Embodiments are not limited thereto. As an example, the circuit area CA may not overlap with the light emission area EA, or may at least partially overlap with the light emission area EA. As an example, the circuit area CA may be placed at least one of an upper side, a lower side, a left side and a right side of the light emission area EA, without being limited thereto.

In the non-light emission area NEA, the plurality of pixels P and a plurality of lines for driving each of the plurality of pixels P can be disposed. The plurality of lines, according to one example, can include a plurality of first signal lines and a plurality of second signal lines.

The plurality of first signal lines may be extended in the second direction (X-axis direction). Each of the plurality of first signal lines may include at least one gate line (or scan line).

Hereinafter, when the first signal line includes a plurality of lines, one first signal line may refer to a signal line group comprised of a plurality of lines. For example, when the first signal line includes two scan lines, one first signal line may refer to a signal line group comprised of two scan lines.

The plurality of second signal lines can extend in the first direction (Y-axis direction). The plurality of second signal lines can intersect with the plurality of first signal lines. Each of the plurality of second signal lines can include a pixel power line EVDD, and a common power line EVSS disposed spaced apart from the pixel power line EVDD. In an embodiment, the plurality of second signal lines can further include a plurality of data lines DL, and a reference line RL. The plurality of data lines DL can include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

Hereinafter, when the second signal line includes a plurality of lines, one second signal line may refer to a signal line group comprised of a plurality of lines. For example, when the second signal line includes four data lines, a pixel power line, a common power line and a reference line, one second signal line may refer to a signal line group comprised of four data lines, a pixel power line, a common power line and a reference line.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. As an example, the non-display area NDA may be disposed to surround the display area DA.

The display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images. According to one example, the pad portion PA may be placed in the non-display area NDA above the display area DA based on FIG. 1. Embodiments are not limited thereto. As an example, the pad portion PA may be placed in the non-display area NDA on any side of the display area DA, without being limited thereto.

The gate driver GD supplies gate signals to the gate lines in accordance with the gate control signal input from the timing controller 190. The gate driver GD may be formed on one side of the display area DA of the display panel or on the non-display area NDA outside both sides of the display area DA in a gate driver in panel (GIP) method as shown in FIG. 1. Alternatively, the gate driver GD may be manufactured as a driving chip, packaged in a flexible film and attached to the non-display area NDA (or the first non-display area) outside one side or both sides of the display area DA of the display panel by a tape automated bonding (TAB) method. Embodiments are not limited thereto. As an example, the gate driver GD may be separately disposed in a separate panel and connected to the non-display area NDA (e.g. the pad portion PAD), for example, in a chip on glass (COG) method, a chip on panel (COP) method, or a chip on film (COF) method, without being limited thereto.

The plurality of gate drivers GD may be separately disposed on a left side of the display area DA, that is, the second non-display area and a right side of the display area DA, that is, the third non-display area. According to one example, the plurality of gate drivers GD may be connected to the plurality of pixels P and the plurality of first signal lines for supplying signals to the plurality of pixels P. The plurality of first signal lines may include at least one signal line for supplying a signal for driving the pixel P.

The plurality of second signal lines may be extended in the first direction (Y-axis direction). The plurality of second signal lines may cross the plurality of first signal lines. The plurality of second signal lines may include a pixel power line EVDD and at least one data line to supply a data voltage to the pixel P. Each of the plurality of second signal lines may be connected to at least one of a plurality of pads, a pixel power shorting bar or a common power shorting bar. The pixel power shorting bar and the common power shorting bar may be disposed in the fourth non-display area that is disposed to face the pad area PA based on the display area DA, without being limited thereto.

The pixels are provided to overlap at least one of the first signal line or the second signal line and emit predetermined light to display an image. The light emission area EA may correspond to an area, which emits light, in the pixel P.

Referring to FIG. 2, the non-light emission area NEA may refer to an area that is provided in the display area DA and does not emit light and may be expressed as a dead zone because it does not emit light. The dead zone according to one example may be an area in which a black matrix and/or a bank is provided, but is not limited thereto, and may refer to an area in which light is not emitted.

The non-light emission area NEA can have the plurality of lines, for example, first signal lines and second signal lines can be disposed. The first signal lines according to one example can include the gate line GL and a sensing line SL disposed extending in the second direction (X-axis direction). The second signal lines according to one example can include the pixel power line EVDD, the common power line EVSS, the reference line RL, and the plurality of data lines DL, which are extending in the first direction (Y-axis direction).

Referring to FIG. 2, the plurality of subpixels SP may include a first subpixel SP1, a second subpixel SP2, a third subpixel SP3, and a fourth subpixel SP4 sequentially adjacent to each other in the second direction (X-axis direction). However, it is not limited thereof, the arrangement structure of the plurality of sub-pixels SPs can be varied depending on the circuit design. For example, the first subpixel SP1, the second subpixel SP2, the third subpixel SP3, and the fourth subpixel SP4 can be arranged in a square shape. Hereinafter, one example in which each of the first to fourth subpixels SP1, SP2, SP3, SP4 are arranged in a row in the second direction (X-axis direction) as shown in FIG. 2 will be described.

Referring to FIG. 3, the display apparatus 100 according to one embodiment of the present disclosure may include the light emitting element layer 120, the color filter layer 130, the first layer 140, and the second layer 150.

The light-emitting element layer 120 is arranged on the substrate 110 and may be included in each of a plurality of subpixels SP. The light-emitting element layer 120 according to one example has a configuration that emits light and may include a pixel electrode 121, an organic light-emitting layer 122, and a counter electrode 123. The light-emitting element layer 120 may be provided between the substrate 110 and the opposing substrate 200.

The color filter layer 130 may be placed between the light-emitting element layer 120 and the substrate 110. The color filter layer 130 according to one example is for converting white light emitted from the light-emitting element layer 120 into light of different colors. The color filter layer 130 may include a first color filter 131 arranged in the green subpixel SP4, a second color filter 132 arranged in a red subpixel SP1, and a third color filter arranged in a blue subpixel SP3.

The first layer 140 may be disposed between the color filter layer 130 and the substrate 110. According to one example, the first layer 140 may be disposed to partially overlap the light emission area EA included in each of the plurality of subpixels SP. The first layer 140 may be a transparent layer. For example, the first layer 140 may include a conductive material, such as IGZO, ITO, FTO, AZO, etc., without being limited thereto.

The second layer 150 may be disposed between the first layer 140 and the color filter layer 130. The second layer 150 may be provided to cover at least a portion of the first layer 140. For example, the second layer 150 may extend from one end of the first layer 140 to the other end to cover at least a portion of an upper surface of the first layer 140. The second layer 150 may be an opaque layer. For example, the second layer 150 may include a conductive material, such as MoTi and/or WOx, without being limited thereto. As an example, the second layer 150 may be provided to overlap at least a portion of the first layer 140. As an example, the second layer 150 may be in contact with the first layer 140. As an example, the second layer 150 may also overlap the light emission area EA.

In the display apparatus 100 according to one embodiment of the present disclosure, the first layer 140 may be provided under the light-emitting element layer 120 (or the pixel electrode 121) to form a capacitance with the pixel electrode 121. Accordingly, in the display apparatus 100 according to one embodiment of the present disclosure, a size (or an area) of the circuit area can be reduced by using the pixel electrode 121 and the first layer 140 as a capacitor (or the first capacitor CT1), and thus a size (or an area) of the light emission area EA can be relatively increased, thereby improving light efficiency.

Meanwhile, in the case of a general display apparatus, external light incident on the substrate can be reflected by a counter electrode and re-emitted to the substrate through a color filter. In this case, since the general display apparatus only has a transparent layer placed under a pixel electrode, there is a problem in that the reflectivity of external light reflected by the counter electrode increases due to the color filter and the transparent layer, thereby reducing a visibility of an image.

In contrast, the display apparatus 100 according to one embodiment of the present disclosure is provided with an opaque second layer 150 covering at least a portion of the first layer 140 under the light-emitting element layer 120 (or the pixel electrode 121), so that some of the external light EL incident on the substrate 110 can be blocked, thereby reducing the reflectance of the external light reflected on the counter electrode. Therefore, the display apparatus 100 according to one embodiment of the present disclosure can improve a visibility of an image by reducing external light reflectance. As an example, the display apparatus 100 according to one embodiment of the present disclosure can be implemented as a low-reflection display apparatus.

For example, as shown in FIG. 3, external light EL incident on the substrate 110 can be divided into the form of a blocking light EL1 and an emission light EL2. The blocking light EL1 can mean light that is blocked by the second layer 150 after being reflected by the counter electrode 123 and is not emitted to the substrate 110. The emission light EL2 may refer to light that is incident on the substrate 110, reflected by the counter electrode 123, and then emitted back to the substrate 110. Accordingly, the display apparatus 100 according to one embodiment of the present disclosure is provided such that the second layer 150 (or opaque layer) is partially disposed on the first layer 140 (or transparent layer), so that the first layer 140 and the pixel electrode 121 can be used as a capacitor (or first capacitor CT1) while also reducing the external light reflectance.

In addition, since the display apparatus 100 according to one embodiment of the present disclosure can have a reduced external light reflectance due to the second layer 150 (or opaque layer), the display apparatus can have the same light emission efficiency or can have improved light emission efficiency even at lower power compared to a display apparatus without the second layer 150 (or opaque layer), so that the overall power consumption can be reduced.

Meanwhile, in the display apparatus 100 according to one embodiment of the present disclosure, the first layer 140 may include a first area A1 and a second area A2.

The first area A1 may be an area where the first layer 140 is covered by the second layer 150. The second area A2 may be an area in the first layer 140 excluding the first area A1. As described above, the second layer 150 is an opaque layer, and thus may be an area through which light cannot pass. Accordingly, the first area A1 may be a light-blocking area. In contrast, the first layer 140 is a transparent layer, and thus may be an area through which light can pass. Accordingly, the second area A2 may be a light-transmitting area.

As illustrated in FIG. 3, a size (or area) of the first layer 140 may be provided to have a size (or area) that partially overlaps the light emission area EA. Accordingly, the first layer 140 may have a limited size (or area). Therefore, in the display apparatus 100 according to one embodiment of the present disclosure, the area (or size) of the first area A1 covered by the second layer 150 may be provided to be inversely proportional to an area (or size) of the second area A2.

For example, as the area (or size) of the first area A1 increases, the area (or size) of the second area A2 may decrease. On the other hand, as the area (or size) of the first area A1 decreases, the area (or size) of the second area A2 may increase. As the area (or size) of the first area A1 increases, an area (or size) of the light-blocking area increases, so that the reduction in external light reflectance can be increased or maximized. Accordingly, in this case, since the display apparatus 100 according to one embodiment of the present disclosure can increased or maximize the reduction in external light reflectance, the polarizing plate can be omitted, so that the manufacturing cost can be reduced. In addition, since the display apparatus 100 according to one embodiment of the present disclosure can increased or maximize the reduction of external light reflectance, the visibility of the image to the user can be increased or maximized.

On the other hand, if the area (or size) of the first area A1 becomes smaller, an area (or size) of the light-transmitting area becomes larger, so the reduction in external light reflectance may become smaller. However, since the capacitance of the pixel electrode 121 and the first layer 140 may increase, an area (or size) of the circuit area CA may be reduced. Accordingly, in this case, the display apparatus 100 according to one embodiment of the present disclosure can further increase the size of the light emission area EA as much as the area (or size) of the circuit area CA is reduced, so that the light efficiency can be improved. However, the present invention is not limited thereto, and the area (or size) of the first area A1 can be provided to be the same as the area (or size) of the second area A2.

Referring to FIG. 3, in the display apparatus 100 according to one embodiment of the present disclosure, the light-emitting element layer 120 may include a pixel electrode 121 on a color filter layer 130, an organic light-emitting layer 122 on the pixel electrode 121, and a counter electrode 123 on the organic light-emitting layer 122. As described above, the first layer 140 and the pixel electrode 121 may be a first capacitor CT1.

In the display apparatus 100 according to one embodiment of the present disclosure, since the second layer 150 may include MoTi and/or WOx, the second layer 150 and the pixel electrode 121 may form different capacitances. For example, in the display apparatus 100 according to one embodiment of the present disclosure, the second layer 150 and the pixel electrode 121 may be a second capacitor CT2.

As a result, as shown in FIG. 3, the display apparatus 100 according to one embodiment of the present disclosure is provided with the first capacitor CT1 and the second capacitor CT2 adjacent to the first capacitor CT1, so that each of the plurality of sub-pixels SP can be driven using two capacitors. Therefore, the display apparatus 100 according to one embodiment of the present disclosure is equipped with two capacitors, so that the external light reflectance can be effectively controlled without changing the overall capacitance.

As illustrated in FIG. 3, the first layer 140 according to one example may be spaced apart from the pixel electrode 121 by a first distance D1. For example, a passivation layer 111b, a color filter layer 130 (or a first color filter 131), and an overcoat layer 112 may be arranged between the first layer 140 and the pixel electrode 121. Accordingly, the first layer 140 can be spaced apart from the pixel electrode 121 by the first distance D1, and thus, the first layer 140 and the pixel electrode 121 can be provided with a first capacitor CT1 having a first capacitance Cst1.

According to one example, the second layer 150 may be spaced apart from the pixel electrode 121 by a second distance D2 that is shorter (e.g., less) than the first distance D1. For example, a passivation layer 111b, a color filter layer 130 (or a first color filter 131), and an overcoat layer 112 may be disposed between the second layer 150 and the pixel electrode 121. However, since the second layer 150 is arranged on an upper surface of the first layer 140, the second layer 150 can be spaced from the pixel electrode 121 by a second distance D2 shorter than the first distance D1. As a result, the second layer 150 and the pixel electrode 121 can be provided with a second capacitor CT2 having a second capacitance Cst2. Embodiments are not limited thereto. As an example, the second layer 150 may not overlap the first layer 140. As an example, the second layer 150 and the first layer 140 may be disposed on the same layer without overlapping with each other. As an example, the second layer 150 may contact with the first layer 140 or may be spaced apart from the first layer 140. As an example, the second layer 150 and the first layer 140 may have the same thickness such that the upper surfaces of the second layer 150 and the first layer 140 are provided in the same plane, without being limited thereto. As an example, the second layer 150 and the first layer 140 may have different thicknesses.

Hereinafter, with reference to FIG. 3, the structure of each of the plurality of sub-pixels SPs will be described in detail.

Referring to FIG. 3, a display apparatus 100 according to one embodiment of the present disclosure can include a buffer layer BL, a circuit element layer 111, a thin film transistor (not shown), an overcoat layer 112, a pixel electrode 121, a bank BK, an organic light emitting layer 122, a counter electrode 123, a filling layer 113, a color filter 130, a first layer 140, and a second layer 150, without being limited thereto.

In more detail, each of the subpixels SP according to one embodiment may include a circuit element layer 111 provided on an upper surface of the buffer layer BL, including a gate insulating layer 111a (or an interlayer insulating layer) and a passivation layer 111b, an overcoat layer 112 provided on the circuit element layer 111, a color filter layer 130 between the overcoat layer 112 and the circuit element layer 111, a first layer 140 between the color filter layer 130 and the circuit element layer 111, a second layer 150 between the first layer 140 and the color filter layer 130, a pixel electrode 121 provided on the overcoat layer 112, a bank BK covering one edge of the pixel electrode 121, an organic light-emitting layer 122 on the pixel electrode 121 and the bank BK, a counter electrode 123 on the organic light-emitting layer 122, a filling layer 113 on the counter electrode 123, and an opposing substrate 200 on the filling layer 113. Embodiments are not limited thereto. As an example, at least one of the above-mentioned components may be omitted, and/or one or more additional component may be further included.

The thin film transistor (not shown) for driving the subpixel SP may be disposed on the circuit element layer 111. The circuit element layer 111 may be expressed as the term of an inorganic film layer. The buffer layer BL may be included in the circuit element layer 111 together with the gate insulating layer 111a (or the interlayer insulating layer) and the passivation layer 111b. The pixel electrode 121, the organic light emitting layer 122 and the counter electrode 123 may be included in the light emitting element layer 120.

The buffer layer BL may be formed between the substrate 110 and the gate insulating layer 111a (or the interlayer insulating layer) to protect the thin film transistor 112. The buffer layer BL may be disposed on the entire surface (or front surface) of the substrate 110. The pixel power line EVDD for pixel driving may be disposed between the buffer layer BL and the substrate 110. The reference line RL may also be disposed between the buffer layer BL and the substrate 110. The reference line RL may be disposed in the non-light emission area NEA that does not overlap with the light emission area EA. The buffer layer BL may serve to block diffusion of a material contained in the substrate 110 into a transistor layer during a high temperature process of a manufacturing process of the thin film transistor. Optionally, the buffer layer BL may be omitted in some cases.

The pixel power line EVDD may be disposed below the bank BK while being spaced apart from the thin film transistor. According to one example, the pixel power line EVDD may include a first pixel power line EVDD1 and a second pixel power line EVDD2. The first pixel power line EVDD1 may be a line that extends long in the first direction (Y-axis direction) as shown in FIG. 2. The second pixel power line EVDD2 may be a line connected to the thin film transistor. The second pixel power line EVDD2 may be arranged in a different layer from the first pixel power line EVDD1. For example, the first pixel power line EVDD1 may be placed between the substrate 110 and the buffer layer BL. Furthermore, the second pixel power line EVDD2 may be placed between the gate insulating layer 111a and the passivation layer 111b. Although not shown, the second pixel power line EVDD2 can be electrically connected to the first pixel power line EVDD1. As an example, the second pixel power line EVDD2 may overlap with the first pixel power line EVDD1, without being limited thereto. Accordingly, the second pixel power line EVDD2 can transmit (or apply) a driving voltage (or driving signal) applied through the first pixel power line EVDD1 to the thin film transistor.

Meanwhile, in the display apparatus 100 according to one embodiment of the present disclosure, the pixel power line EVDD may be arranged apart from the first layer 140. As described above, since the first layer 140 functions as the pixel electrode 121 and the first capacitor CT1, if the first pixel power line EVDD1 is placed close to the first layer 140, a line load of the first pixel power line EVDD1 can increase. In addition, if the second pixel power line EVDD2 is placed close to the first layer 140, the driving voltage (or driving signal) applied to the thin film transistor may interfere with the first capacitance, resulting in a driving failure of the light emitting element layer 120. Accordingly, in the display apparatus 100 according to one embodiment of the present disclosure, the pixel power line EVDD is arranged to be spaced apart from the first layer 140 (or the second layer 150), thereby reducing or preventing or at least reducing an increase in the line load of the first pixel power line EVDD1 and reducing or preventing a failure of the driving voltage (or driving signal) applied to the thin film transistor.

The thin film transistor (or a drive transistor) according to an example may include an active layer, a gate electrode, a source electrode, and a drain electrode.

The active layer may include a channel area, a drain area and a source area, which are formed in a thin film transistor area of a circuit area of the subpixel SP. The drain area and the source area may be spaced apart from each other with the channel area interposed therebetween.

The active layer may be formed of a semiconductor material based on any one of amorphous silicon, polycrystalline silicon, oxide and organic material.

The gate insulating layer 111a may be formed on the channel area of the active layer. As an example, the gate insulating layer 111a may be formed in an island shape only on the channel area of the active layer or may be formed on an entire front surface of the substrate 110 or the buffer layer BL, which includes the active layer.

The gate electrode may be formed on the gate insulating layer 111a to overlap the channel area of the active layer.

The interlayer insulating layer can be formed to partially overlap the gate electrode and the drain area and source area of the active layer. The interlayer insulating layer may be formed in an entire light emission area, in which light is emitted to the subpixel SP. However, embodiments of the present disclosure are not limited thereto, the interlayer insulating layer 111b may be patterned between the drain electrode and the gate electrode and drain area of the active layer and may be arranged in an island shape, and moreover, may be patterned between the source electrode and the gate electrode and source area of the active layer and may be arranged in an island shape.

The source electrode may be electrically connected to the source area of the active layer through a source contact hole provided in the interlayer insulating layer overlapped with the source area of the active layer. The drain electrode may be electrically connected to the drain area of the active layer through a drain contact hole provided in the interlayer insulating layer overlapped with the drain area of the active layer.

The drain electrode and the source electrode may be made of the same metal material. For example, each of the drain electrode and the source electrode may be made of a single metal layer, a single layer of an alloy or a multi-layer of two or more layers, which is the same as or different from that of the gate electrode.

Additionally, in order to reduce or prevent or at least reduce a threshold voltage of the thin film transistor provided in a pixel area from being shifted by light, the display panel or the substrate 110 may further include a light shielding layer provided below the active layer of at least one of the thin film transistors, including a driving thin film transistor, a first switching thin film transistor or a second switching thin film transistor, without being limited thereto. The light shielding layer may be disposed between the substrate 110 and the active layer to shield light incident on the active layer through the substrate 110, thereby reducing or minimizing or at least reducing a change in the threshold voltage of the transistor due to external light. Also, since the light shielding layer is provided between the substrate 110 and the active layer, the thin film transistor may be reduced or prevented from being seen by a user.

The passivation layer 111b may be provided on the substrate 110 to cover the pixel area. The passivation layer 111b covers a drain electrode, a source electrode and a gate electrode of the thin film transistor, and the buffer layer BL. The passivation layer 111b may be formed over the circuit area and the light emission area. The passivation layer 111b may be omitted.

Meanwhile, as illustrated in FIG. 3, the pixel power line EVDD may be arranged to overlap the bank BK in the third direction (Z-axis direction). In addition, as illustrated in FIG. 3, a width BKW of the bank BK may be provided to be wider than a width EW of the pixel power line EVDD. Accordingly, the display apparatus 100 according to one embodiment of the present disclosure is provided such that the pixel power line EVDD does not overlap the light emission area EA, thereby reducing or preventing or at least reducing light emitted from the light-emitting element layer 120 from being blocked by the pixel power line EVDD and resulting in a decrease in light efficiency. As an example, the display apparatus 100 according to one embodiment of the present disclosure is provided so that the pixel power line EVDD does not overlap with the light emission area EA, so that a sufficient aperture area through which light can be emitted can be secured.

The overcoat layer 112 may be provided on the substrate 110 to cover the passivation layer 111b. When the passivation layer 111b is omitted, the overcoat layer 112 may be provided on the substrate 110 to cover the circuit area (or the thin film transistor 112). The overcoat layer 112 may be formed in the circuit area CA in which the thin film transistor is disposed and the light emission area EA. In addition, the overcoat layer 112 may be formed in the other non-display area NDA except a pad area PA of the non-display area NDA and the entire display area DA. For example, the overcoat layer 112 may include an extension portion (or an enlarged portion) extended or enlarged from the display area DA to the other non-display area NDA except the pad area PA. Therefore, the overcoat layer 112 may have a size relatively wider than that of the display area DA, without being limited thereto.

The overcoat layer 112 according to one example may be formed to have a relatively thick thickness, thereby providing a flat surface on the display area DA and the non-display area NDA. For example, the overcoat layer 112 may be made of an organic material such as photo acryl, benzocyclobutene, polyimide and fluorine resin, without being limited thereto.

On the other hand, the upper surface of the overcoat layer 112 can be provided flatly. Accordingly, the pixel electrodes 121 on the overcoat layer 112 can also be provided flatly, and the organic light emitting layer 122 and the counter electrode 123 formed thereon can also be provided flatly. Since the pixel electrode 121, the organic light emitting layer 122, the counter electrode 123, that is, the light emitting element layer 120 is provided to be flat in the light emission area EA, a thickness of each of the pixel electrode 121, the organic light emitting layer 122 and the counter electrode 123 in the light emission area EA may be uniformly formed. Therefore, the organic light emitting layer 122 may be uniformly emitted without deviation in the light emission area EA.

The color filter layer 130 may be arranged between the overcoat layer 112 and the circuit element layer 111. According to an example, the color filter layer 130 may include a first color filter 131 arranged in the green subpixel SP4, a second color filter 132 arranged in the red subpixel SP1, and a third color filter arranged in the blue subpixel SP3. The white subpixel SP2 is equipped to emit white light and therefore may not include a color filter. The color filter layer 130 is arranged between the first layer 140 and the pixel electrode 121 together with the overcoat layer 112 and the passivation layer 111b, thereby maintaining a gap between the first layer 140 and the pixel electrode 121 so that the first layer 140 and the pixel electrode 121 can function as a first capacitor CT1. In addition, the color filter layer 130 is disposed between the second layer 150 and the pixel electrode 121 together with the overcoat layer 112 and the passivation layer 111b, thereby maintaining a gap between the second layer 150 and the pixel electrode 121 so that the second layer 150 and the pixel electrode 121 can function as a second capacitor CT2.

The first layer 140 may be arranged between the color filter 130 and the circuit element layer 111. The first layer 140 according to one example may be a transparent layer. As shown in FIG. 3, the first layer 140 may be arranged to partially overlap the light emission area EA included in each of the plurality of subpixels SP, thereby forming the pixel electrode 121 and the first capacitance Cst1.

The second layer 150 may be placed between the first layer 140 and the color filter layer 130 (or the passivation layer 111b), without being limited thereto. The second layer 150 according to one example may be an opaque layer. As shown in FIG. 3, the second layer 150 may be provided to cover at least a portion of the first layer 140, thereby blocking external light reflected by the counter electrode 123 from being emitted to the substrate 110. Additionally, the second layer 150 can be arranged to partially overlap the light emission area EA to form the pixel electrode 121 and the second capacitance Cst2.

The pixel electrodes 121 according to one example can be formed on the overcoat layer 112. Although not shown, the pixel electrode 121 may be connected to a drain electrode or a source electrode of the thin film transistor through a contact hole passing through the overcoat layer 112 and the passivation layer 111b. The one edge portion of the pixel electrode 121 may be covered by the bank BK, without being limited thereto. The pixel electrode 121 may be made of at least one of a transparent metal material or a semi-transmissive metal material, without being limited thereto.

Because the display apparatus 100 according to an embodiment of the present disclosure is configured as the bottom emission type, the pixel electrode 121 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag, without being limited thereto.

Meanwhile, the material constituting the pixel electrode 121 may include MoTi. The pixel electrode 121 may be a first electrode or an anode electrode.

The bank BK may be an area, which does not emit light, and disposed on one side of the light emission area EA of each of the plurality of sub-pixels SP. For example, the bank BK may be disposed in the non-light emission area NEA. The bank BK may be formed to cover a portion where the edge of the pixel electrode 121, without being limited thereto. Accordingly, the bank BK may reduce or prevent the pixel electrode 121 and the counter electrode 123 in the edge of the pixel electrode 121. The exposed portion of the pixel electrode 121 that is not covered by the bank BK may be included in the light emitting portion (or light emission area EA).

After the bank BK is formed, an organic light emitting layer 122 may be formed to cover the pixel electrodes 121 and the bank BK. Thus, the bank BK may be provided between the pixel electrodes 121 and the organic light emitting layer 122. The bank BK may be expressed in terms of a pixel-defining membrane. The bank BK according to one example may comprise organic material and/or inorganic material.

Referring again back to FIG. 3, the organic light emitting layer 122 may be formed on the pixel electrodes 121 and the bank BK. According to one example, the organic light emitting layer 122 may be disposed in the light emission area EA and the non-light emission area NEA. The organic light emitting layer 122 may be provided between the pixel electrode 121 and the counter electrode 123. Thus, when a voltage is applied to each of the pixel electrode 121 and the counter electrode 123, an electric field is formed between the pixel electrode 121 and the counter electrode 123. Therefore, the organic light emitting layer 122 may emit light. The organic light emitting layer 122 may be formed of a plurality of subpixels SP and a common layer provided on the bank BK.

The organic light emitting layer 122 according to an embodiment may be provided to emit white light. The organic light emitting layer 122 may include a plurality of stacks which emit lights of different colors, without being limited thereto. For example, the organic light emitting layer 122 may include a first stack, a second stack, and a charge generating layer (CGL) provided between the first stack and the second stack. The light emitting layer may be provided to emit the white light, and thus, each of the plurality of subpixels SP may include a color filter 130 suitable for a corresponding color.

The first stack may be provided on the pixel electrode 121 and may be implemented a structure where a hole injection layer (HIL), a hole transport layer (HTL), an emission layer (EML(B)), and an electron transport layer (ETL) are sequentially stacked. Embodiments are not limited thereto. As an example, at least one of the hole injection layer (HIL), the hole transport layer (HTL), and the electron transport layer (ETL) may be omitted depending on the design.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant, without being limited thereto.

The second stack may be provided on the first stack and may be implemented in a structure where a hole transport layer (HTL), a yellow-green (YG) emission layer (EML(YG)), and an electron injection layer (EIL) are sequentially stacked, without being limited thereto.

In the display apparatus 100 according to an embodiment of the present disclosure, because the organic light emitting layer 122 is provided as a common layer, the first stack, the charge generating layer, and the second stack may be arranged all over the plurality of subpixels SP. The organic light emitting layer 122, according to another example, may be provided in a three-stacked structure or a four-stacked structure, depending on the number of stacks stacked. Embodiments are not limited thereto. As an example, at least one or all of the first stack, the charge generating layer, and the second stack may be arranged all over some of the plurality of subpixels SP, or may be individually arranged in each of the plurality of subpixels SP, without being limited thereto.

The counter electrode 123 may be formed on the organic light emitting layer 122. The counter electrode 123 may be disposed in the light emission area EA and the non-light emission area NEA. The counter electrode 123 according to one example may include a metal material, without being limited thereto. The counter electrode 123 may reflect the light emitted from the organic light emitting layer 122 in the plurality of subpixels SP toward a lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 122 toward the substrate 110, and thus the counter electrode 123 may be made of a material having high reflectance (e.g., a metal material). The counter electrode 123 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu), without being limited thereto. The counter electrode 123 may be expressed as terms such as a second electrode, a cathode electrode and a reflective electrode.

The filling layer 113 is formed on the counter electrode 123. The filling layer 113 serves to reduce or prevent or at least reduce oxygen or moisture from penetrating into the organic light emitting layer 122 and the counter electrode 123. To this end, the filling layer 113 can be configured to include a getter capable of absorbing oxygen or moisture, without being limited thereto. Alternatively, the filling layer 113 can comprise a plurality of layers including at least one inorganic film and at least one organic film.

On the other hand, as shown in FIG. 3, the filling layer 113 can be disposed not only in the light emission area EA but also in the non-light emission area NEA. The filling layer 113 can be disposed between the counter electrodes 123 and the opposing substrate 200.

Meanwhile, in the display apparatus 100 according to one embodiment of the present disclosure, the plurality of subpixels SP may include two subpixels equipped to emit different colors. For example, the plurality of subpixels SP may include a first subpixel SP1 equipped to emit red light and a fourth subpixel SP4 equipped to emit green light. As shown in FIG. 3, the fourth subpixel SP4 may include a first color filter 131, which is a green color filter, so that green light is emitted. In addition, the first subpixel SP1 may include a second color filter 132, which is a red color filter, so that red light is emitted. As shown in FIG. 3, the first color filter 131 may be provided to partially overlap the second color filter 132 under the bank BK. For example, a part of the first color filter 131 between the bank BK and the pixel power line EVDD may be arranged to overlap a part of the second color filter 132 between the bank BK and the pixel power line EVDD in the third direction (Z-axis direction). Accordingly, in the display apparatus 100 according to one embodiment of the present disclosure, two different color filters are arranged to overlap each other between a plurality of subpixels SP, so that light emitted from an emitting subpixel SP can be reduced or prevented from being emitted to a non-emitting subpixel SP, thereby reducing or preventing color mixing. Furthermore, since the display apparatus 100 according to one embodiment of the present disclosure has two different color filters arranged to overlap each other between a plurality of sub-pixels SP, a separate black matrix can be omitted, so that manufacturing costs can be reduced. Embodiments are not limited thereto. As an example, the different color filters may not be arranged to overlap each other between a plurality of sub-pixels SP. As an example, a separate black matrix may be further included.

Referring again to FIG. 3, in the display apparatus 100 according to one embodiment of the present disclosure, a width W3 of the first layer 140 may be provided to be smaller than a width W4 of the pixel electrode 121 that is not covered by the bank BK, without being limited thereto.

Specifically, the bank BK may be provided to cover the edge of the pixel electrode 121 included in each of the plurality of subpixels SP. For example, as shown in FIG. 3, the bank BK may be provided to cover the edges on both sides of the pixel electrode 121. Accordingly, the light emission area EA of each of the plurality of subpixels SP can be defined by the bank BK. Therefore, as shown in FIG. 3, the width W4 of the pixel electrode 121 not covered by the bank BK can be a width of the light emission area EA.

Since the first layer 140 must form a capacitance with the pixel electrode 121, it can be arranged to overlap the light emission area EA. Accordingly, a width of the first layer 140 can be provided to be equal to or smaller than a width of the pixel electrode 121. However, if the width of the first layer 140 is formed to be the same as the width of the pixel electrode 121, the first layer 140 is placed close to the pixel power line EVDD, so not only may the line load of the pixel power line EVDD increase, but also a defect may occur in the driving voltage (or driving signal) applied to the thin film transistor. Accordingly, the display apparatus 100 according to one embodiment of the present disclosure is provided such that the width W3 of the first layer 140 is smaller than the width W4 of the pixel electrode 121 that is not covered by the bank BK (or a width W4 of the light emission area EA), so that capacitance between the first layer 140 and the pixel electrode 121 can be formed, while an increase in the line load of the pixel power line EVDD can be reduced or prevented, and a failure of the driving voltage (or driving signal) can be reduced or prevented.

Therefore, the display apparatus 100 according to one embodiment of the present disclosure may be provided such that the first layer 140 is spaced apart from the end of the light emission area EA by a predetermined width W5. The predetermined width W5 may be in a direction parallel to the second direction (X-axis direction). In addition, the predetermined width W5 may be a width for a process margin of the first layer 140 and the pixel electrode 121, without being limited thereto.

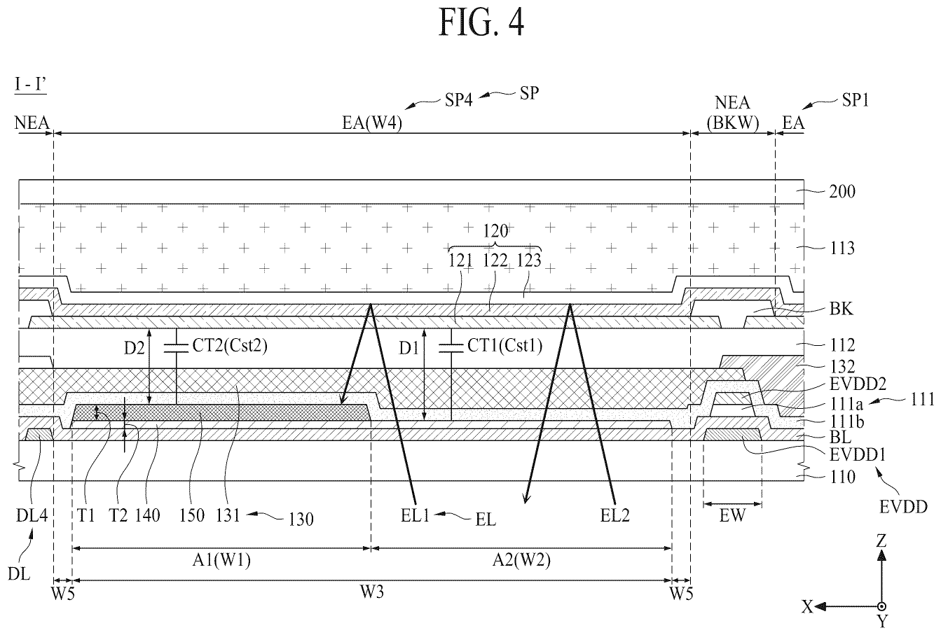

FIG. 4 is a schematic cross-sectional view of a display apparatus according to a second embodiment of the present disclosure.

Referring to FIG. 4, the display apparatus 100 according to the second embodiment of the present disclosure is the same as the transparent display apparatus according to FIG. 1 described above, except that a thickness of the second layer 150 is changed. Therefore, the same drawing symbols have been assigned to the same configuration, and only the different configurations will be described hereinafter.

In the case of the display apparatus according to FIG. 1, the second layer 150 disposed on the first layer 140 may be provided with a thickness similar to or the same as that of the first layer 140. Accordingly, in the case of the display apparatus according to FIG. 1, assuming that the size (or area) of the first area A1 and the size (or area) of the second area A2 are the same on a plane, the first capacitance Cst1 of the first capacitor CT1 and the second capacitance Cst2 of the second capacitor CT2 can be provided to be almost the same. In the case of the display apparatus according to FIG. 1, the difference between the first distance D1 forming the first capacitance Cst1 and the second distance D2 forming the second capacitance Cst2 is not large.

In contrast, in the case of the display apparatus according to FIG. 4, a thickness T1 of the second layer 150 may be provided to be thicker than a thickness T2 of the first layer 140. For example, the thickness T1 of the second layer 150 may be provided to be about 2 times, 5 times, 10 times, 20 times, 30 times thicker than the thickness T2 of the first layer 140. Accordingly, in the case of the display apparatus according to FIG. 4, the second distance D2 forming the second capacitance Cst2 may be provided to be shorter than the first distance D1 forming the first capacitance Cst1. Therefore, in the case of the display apparatus 100 according to FIG. 4, assuming that the size (or area) of the first area A1 and the size (or area) of the second area A2 are the same on a plane, the second capacitance Cst2 of the second capacitor CT2 may be provided to be greater than the first capacitance Cst1 of the first capacitor CT1.

As a result, the display apparatus 100 according to the second embodiment of the present disclosure can be provided with the second capacitance Cst2 larger than the first capacitance Cst1 while maintaining the same level of external light reflectance reduction as the display apparatus according to FIG. 1 by having the thickness T1 of the second layer 150 thicker than the thickness T2 of the first layer 140.

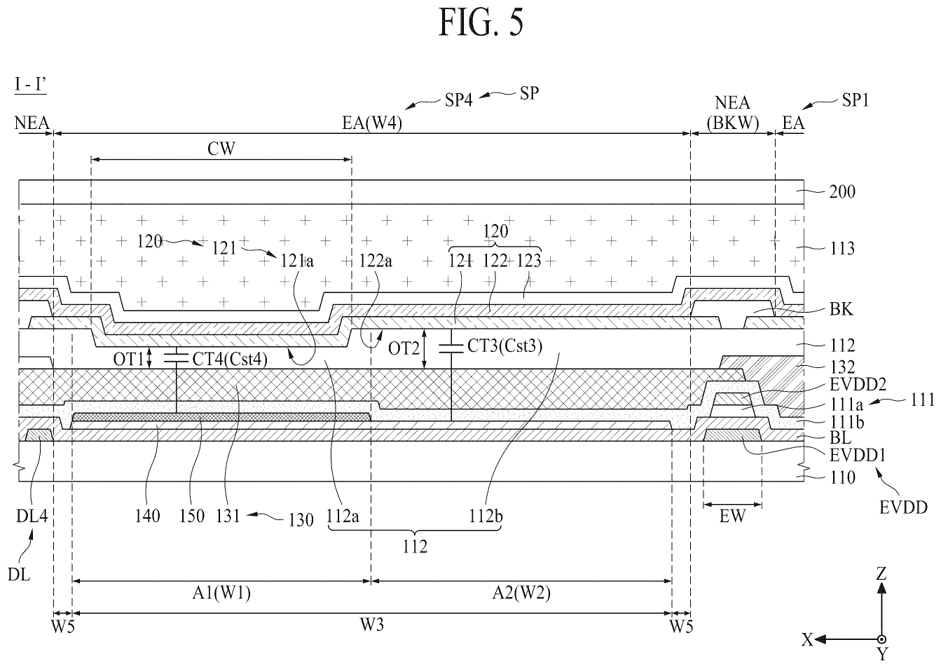

FIG. 5 is a schematic cross-sectional view of a display apparatus according to a third embodiment of the present disclosure.

Referring to FIG. 5, the display apparatus 100 according to the third embodiment of the present disclosure is the same as the transparent display apparatus according to FIG. 1 described above, except that the structure of the overcoat layer 112 and the pixel electrode 121 is changed. Therefore, the same drawing symbols have been assigned to the same configuration, and only the different configurations will be described hereinafter.

In the case of the display apparatus according to FIG. 1, the overcoat layer 112 (or an upper surface of the overcoat layer 112) and the pixel electrode 121 (or an upper surface of the pixel electrode 121) are provided flat in the light emission area EA. Accordingly, in the case of the display apparatus according to FIG. 1, since the difference between the first distance D1 forming the first capacitance Cst1 and the second distance D2 forming the second capacitance Cst2 is not large, the first capacitance Cst1 of the first capacitor CT1 and the second capacitance Cst2 of the second capacitor CT2 can be provided to be almost the same.

In contrast, in the case of the display apparatus according to FIG. 5, the pixel electrode 121 may be provided to include a concave portion 121a and a flat portion 121b. According to an example, the concave portion 121a may be provided to be sunken in the direction from the counter electrode 123 toward the substrate 110. According to an example, the flat portion 121b may be positioned further away from the substrate 110 than the concave portion 121a. Accordingly, in the case of the display apparatus according to FIG. 5, a third capacitance Cst3 (or the first capacitance Cst1) of a third capacitor CT3 formed between the flat portion 121b and the first layer 140 may be provided to be smaller than a fourth capacitance Cst4 of a fourth capacitor CT4 formed between the concave portion 121a and the second layer 150. However, in this case, it can be assumed that the size (or area) of the first area A1 and the size (or area) of the second area A2 on the plane are the same.

In the case of the display apparatus according to FIG. 5, the overcoat layer 112 in which the concave portion 121a is formed can be etched more than the overcoat layer 112 in which the flat portion 121b is formed through the half-tone mask, and the pixel electrode 121 is formed along the profile of the overcoat layer 112. Accordingly, in the case of the display apparatus according to FIG. 5, a thickness OT1 of a first overcoat layer 112a between the concave portion 121a and the color filter layer 130 may be thinner than a thickness OT2 of a second overcoat layer 112b between the flat portion 121b and the color filter layer 130. As shown in FIG. 5, the second overcoat layer 112b can be connected to the first overcoat layer 112a.

As a result, the display apparatus 100 according to the third embodiment of the present disclosure is provided such that the pixel electrode 121 includes the concave portion 121a and the flat portion 121b, so that the thickness OT1 of the first overcoat layer 112a can be provided thinner than the thickness OT2 of the second overcoat layer 112b, and thus the fourth capacitance Cst4 can be provided to be larger than the third capacitance Cst3 (or the first capacitance Cst1).

The display apparatus 100 according to the third embodiment of the present disclosure is provided such that the pixel electrode 121 includes the concave portion 121a and the flat portion 121b, so that the fourth capacitance Cst4 can be provided to be larger than the third capacitance Cst3 (or the first capacitance Cst1) while maintaining the same level of external light reflectance reduction compared to the display apparatus according to FIG. 1.

Meanwhile, the display apparatus 100 according to the third embodiment of the present disclosure is provided such that the pixel electrode 121 includes the concave portion 121a and the flat portion 121b, so that the organic light-emitting layer 122 formed on the pixel electrode 121 can be formed along the profile of the concave portion 121a and the flat portion 121b, and thus, the organic light-emitting layer 122 can have a structural feature including a concave portion and a flat portion.

Referring again to FIG. 5, in the display apparatus 100 according to the third embodiment of the present disclosure, a width CW of the concave portion 121a may be provided to be equal to or smaller than a width W1 of the second layer 150. If the width CW of the concave portion 121a is wider than the width W1 of the second layer 150, the concave portion 121a protruding beyond the second layer 150 does not form a capacitance with the second layer 150. In addition, since the concave portion 121a protruding more than the second layer 150 overlaps the second area A2, the viewing angle of the light emitted from the organic light-emitting layer 122 may be distorted, causing color mixing. Accordingly, the display apparatus 100 according to the third embodiment of the present disclosure is provided with the width CW of the concave portion 121a equal to or smaller than the width W1 of the second layer 150, so that the fourth capacitance Cst4 between the concave portion 121a and the second layer 150 can be uniformly maintained while color mixing can be reduced or prevented.

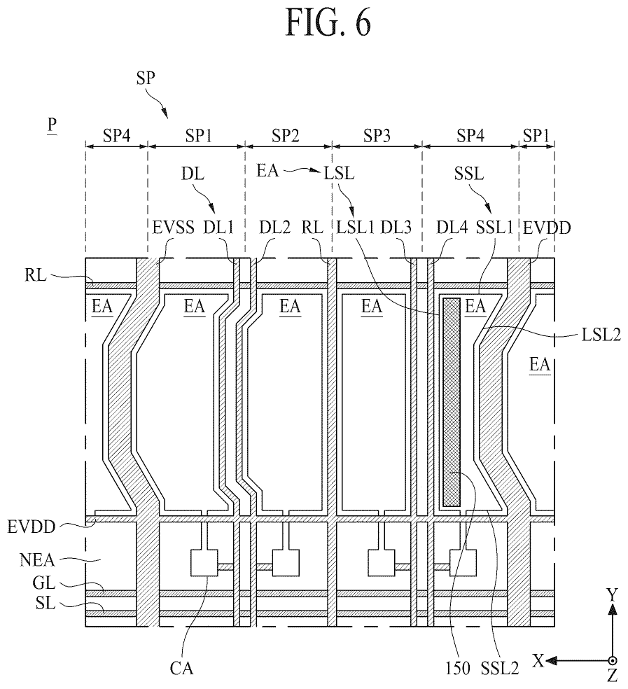

FIG. 6 is a plan view showing one example of a second layer arranged in a light emission area of a display apparatus according to one embodiment of the present disclosure.

Referring to FIG. 6, in the display apparatus 100 according to one embodiment of the present disclosure, the light emission area EA may include a plurality of short sides SSL and a plurality of long sides LSL connected to the plurality of short sides SSL. For example, the plurality of short sides SSL may be sides that are elongated in the second direction (X-axis direction). With respect to the fourth sub-pixel SP4 of FIG. 6, the plurality of short sides SSL may include a first short side SSL1 positioned above the light emission area EA and a second short side SSL2 positioned below the light emission area EA. The plurality of long sides LSL may be sides that are elongated in the first direction (Y-axis direction). With respect to the fourth sub-pixel SP4 of FIG. 6, the plurality of long sides LSL may include a first long side LSL1 located on a left side of the light emission area EA and a second long side LSL2 located on a right side of the light emission area EA. Embodiments are not limited thereto. As an example, the light emission area EA may have various shapes such as a square shape, a circular shape, an oval shape, a triangle shape, a polygonal shape, etc., other than a rectangular shape. In this case, the light emission area EA may include no long sides or short sides.

Referring to FIG. 6, one example of the second layer 150 of the display apparatus 100 according to one embodiment of the present disclosure may be provided such that the second layer 150 extends along one of the plurality of long sides LSL and is positioned adjacent to each of the plurality of short sides SSL. For example, as shown in FIG. 6, the second layer 150 may be elongated in the first direction (Y-axis direction) along the first long side LSL1 and may be arranged adjacent to each of the first short side SSL1 (or a part of the first short side SSL1) and the second short side SSL2 (or a part of the second short side SSL2). Therefore, as shown in FIG. 6, the second layer 150 can be placed at approximately half (or a left part of the light emission area EA) of the light emission area EA based on the second direction (X-axis direction). In this case, the display apparatus 100 according to one embodiment of the present disclosure is provided such that the second layer 150 is disposed on the left side of the light emission area EA, so that external light EL incident on the substrate 110 can be reduced or prevented from being emitted toward the third subpixel SP3 by the second layer 150, and thus color mixing due to external light can be reduced or prevented or at least reduced. As an example, the second layer 150 can be placed in the light emission area EA adjacent to the light emission area EA of an adjacent subpixel. As an example, the second layer 150 can be placed adjacent to one side of the light emission area EA adjacent to the light emission area EA of an adjacent subpixel, and may be arranged adjacent to sides of the light emission area EA connected to the one side, without being limited thereto.

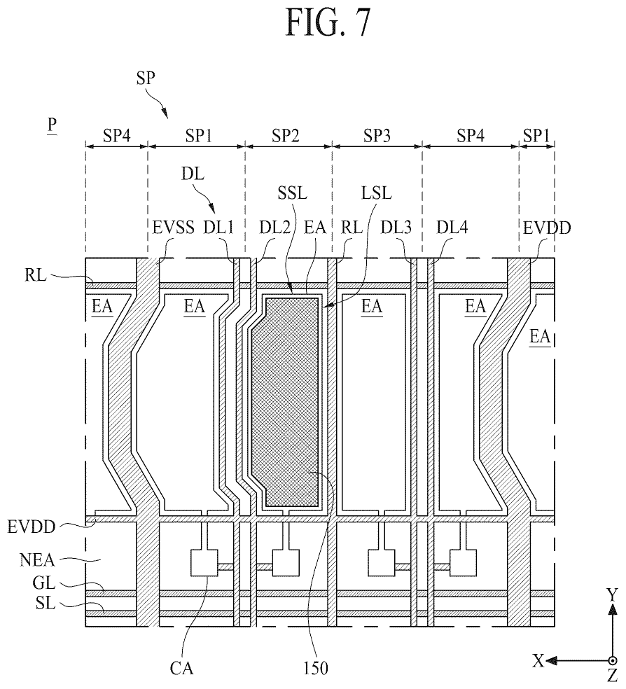

FIG. 7 is a plan view showing a second example of a second layer arranged in a light emission area of a display apparatus according to one embodiment of the present disclosure.

Referring to FIG. 7, a second example of the second layer 150 of a display apparatus 100 according to one embodiment of the present disclosure may be provided such that the second layer 150 is arranged to overlap mostly with an emitting area EA of one of the plurality of subpixels SP. As an example, the second layer 150 may be arranged to overlap with an emitting area EA of only one of the plurality of subpixels SP constituting one unit pixel, while the first layer 140 is disposed in each of the plurality of subpixels SP constituting one unit pixel, without being limited thereto. For example, as shown in FIG. 7, the second layer 150 may be arranged to overlap mostly with the light emission area EA of the second subpixel SP2, which is a white subpixel. In this case, the second layer 150 may be arranged adjacent to each of the plurality of long sides LSL and the plurality of short sides SSL of the light emission area EA of the second subpixel SP2, without being limited thereto. Accordingly, the second example of the second layer 150 of the display apparatus 100 according to one embodiment of the present disclosure may be provided such that the second layer 150 covers most of the light emission area EA of the white subpixel, so that black lifting can be reduced or prevented compared to a case where the second layer is not present in the white subpixel, and thus real black can be implemented.

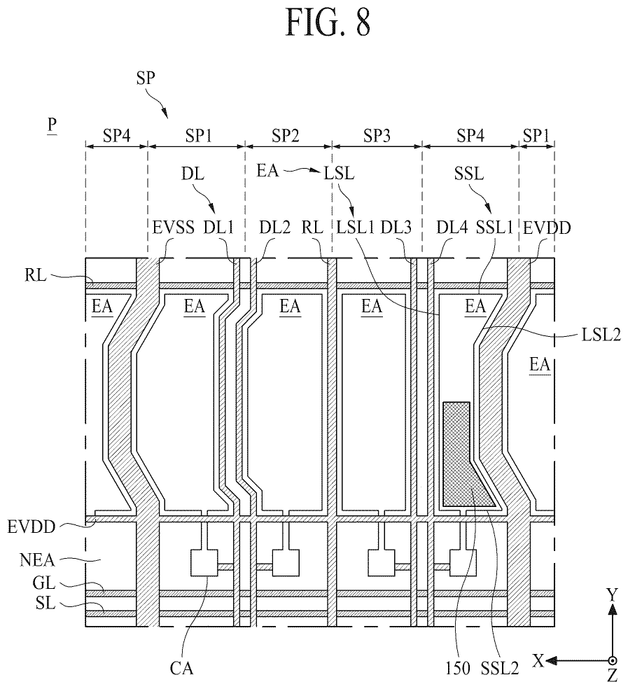

FIG. 8 is a plan view showing a third example of a second layer arranged in a light emission area of a display apparatus according to one embodiment of the present disclosure.

Referring to FIG. 8, a third example of the second layer 150 of a display apparatus 100 according to one embodiment of the present disclosure may be provided such that the second layer 150 extends along one short side SSL of the plurality of long sides LSL and is positioned adjacent to each of the plurality of long sides LSL. For example, as shown in FIG. 8, the second layer 150 may be elongated in the second direction (X-axis direction) along the second long side LSL2 and may be arranged adjacent to each of the first long side LSL1 (or a part of the first long side LSL1) and the second long side LSL2 (or a part of the second long side LSL2). Accordingly, as shown in FIG. 8, the second layer 150 can be placed at approximately half (or a lower portion of the light emission area EA) of the light emission area EA based on the first direction (Y-axis direction). In this case, the display apparatus 100 according to one embodiment of the present disclosure is provided such that the second layer 150 is disposed at the lower portion of the light emission area EA, so that external light EL incident on the substrate 110 can be reduced or prevented from being emitted toward another subpixel disposed below the fourth subpixel SP4 by the second layer 150, and thus color mixing due to external light can be reduced or prevented or at least reduced. In addition, since the display apparatus 100 according to one embodiment of the present disclosure is provided such that the second layer 150 is disposed at the lower portion of the light emission area EA, external light (EL) incident on the substrate 110 can be reduced or prevented from being emitted toward the circuit area CA by the second layer 150, and thus deterioration of the circuit area CA included in the corresponding subpixel (or the fourth subpixel SP4) can be reduced or prevented. As an example, the second layer 150 may be placed in the light emission area EA adjacent to the circuit area CA included in the corresponding subpixel. As an example, the second layer 150 may be placed adjacent to one side of the light emission area EA adjacent to the circuit area CA included in the corresponding subpixel, and may be arranged to be adjacent to sides of the light emission area EA connected to the one side, without being limited thereto.

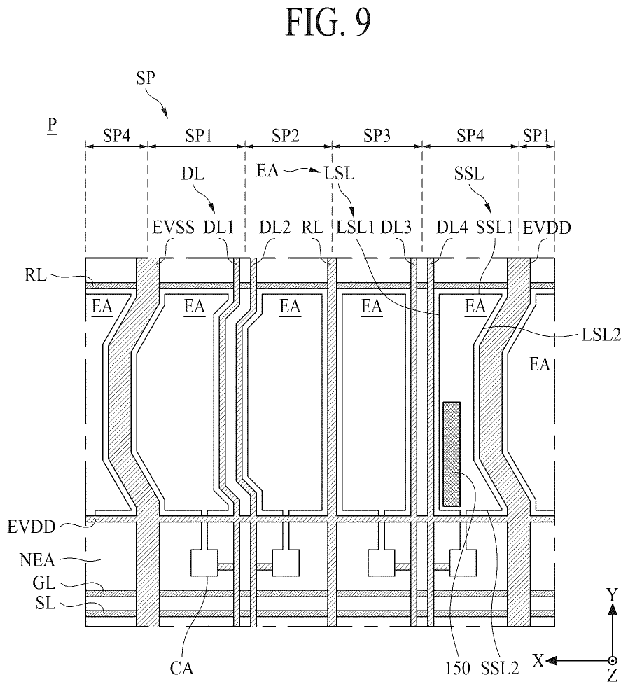

FIG. 9 is a plan view showing a fourth example of a second layer arranged in a light emission area of a display apparatus according to one embodiment of the present disclosure.

Referring to FIG. 9, a fourth example of the second layer 150 of a display apparatus 100 according to one embodiment of the present disclosure may be provided such that the second layer 150 is arranged partially adjacent to one of the short sides SSL of the plurality of short sides SSL and partially adjacent to one of the long sides LSL of the plurality of long sides LSL. For example, the second layer 150 may be arranged to partially extend in the second direction (X-axis direction) along the second short side SSL2 and to partially extend in the first direction (Y-axis direction) along the first long side LSL1. As shown in FIG. 9, the second layer 150 can be arranged adjacent to approximately half of the second short side SSL2 in the first direction (Y-axis direction) and approximately half of the first long side LSL1 in the second direction (X-axis direction). Therefore, the fourth example of the second layer 150 of the display apparatus 100 according to one embodiment of the present disclosure may be such that the second layer 150 may be placed at an edge portion (or corner portion) of the light emission area EA. In this case, the display apparatus 100 according to one embodiment of the present disclosure is provided such that the second layer 150 is disposed at the edge portion (or corner portion) of the light emission area EA, so that external light EL incident on the substrate 110 (or the light emission area EA of the fourth sub-pixel SP) can be reduced or prevented from being emitted toward a circuit area CA of the third sub-pixel SP3 by the second layer 150, and thus deterioration of the circuit area CA of the third sub-pixel SP3 can be reduced or prevented. As an example, the second layer 150 may be placed at a corner portion of the light emission area EA of one subpixel adjacent to a circuit area CA of the one subpixel and a circuit area CA of an adjacent subpixel, without being limited thereto.

Meanwhile, as shown in FIGS. 6 to 9, the display apparatus 100 according to one embodiment of the present disclosure can be equipped to satisfy various user demands for external light reflectance (or image visibility) and/or capacitance since the second layer 150 can be arranged in various shapes in the light emission area EA.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this disclosure shall be construed to be included within the scope of the claims of this disclosure.

The display apparatus according to the present disclosure is provided such that a second layer (or opaque layer) is partially disposed on a first layer (or transparent layer), thereby reducing or minimizing external light reflectance.

The display apparatus according to the present disclosure can improve the visibility of an image due to a reduction in external light reflectance.

Since the display apparatus according to the present disclosure can have a reduced external light reflectance due to the second layer (or opaque layer), the display apparatus can have the same luminous efficiency or have an improved luminous efficiency even at lower power compared to the display apparatus without the second layer (or opaque layer), so that the overall power consumption can be reduced or minimized.

The effects to be obtained from the present disclosure are not limited to those mentioned above, and other effects not mentioned will be apparent to one of ordinary skill in the art from the description.

What is claimed is:

1. A display apparatus comprising:
a substrate having a plurality of pixels, the plurality of pixels including a plurality of subpixels;
a light-emitting element layer on the substrate, the light-emitting element layer included in each of the plurality of subpixels;
a color filter layer between the light-emitting element layer and the substrate;
a first layer between the color filter layer and the substrate; and
a second layer covering at least a portion of the first layer between the first layer and the color filter layer,
wherein the first layer is a transparent layer and the second layer is an opaque layer.

2. The display apparatus of claim 1, wherein the first layer comprises IGZO and the second layer comprises MoTi and/or WOx.

3. The display apparatus of claim 1, wherein the first layer includes a first area covered by the second layer and a second area excluding the first area,
wherein the first area is a light-blocking area and the second area is a light-transmitting area.

4. The display apparatus of claim 3, wherein an area of the first area and an area of the second area are inversely proportional.

5. The display apparatus of claim 1, wherein the light-emitting element layer comprises:
a pixel electrode on the color filter layer;
an organic light-emitting layer on the pixel electrode; and
a counter electrode on the organic light-emitting layer,
wherein the first layer and the pixel electrode are a first capacitor and the second layer and the pixel electrode are a second capacitor.

6. The display apparatus of claim 5, wherein the first layer is spaced apart from the pixel electrode by a first distance and the second layer is spaced apart from the pixel electrode by a second distance that is shorter than the first distance.

7. The display apparatus of claim 5, wherein each of the plurality of subpixels includes a bank covering an edge of the pixel electrode, and
wherein a width of the first layer is smaller than a width of the pixel electrode that is not covered by the bank.

8. The display apparatus of claim 7, wherein the plurality of subpixels include two sub-pixels configured to emit different colors,
wherein the color filter layer includes a first color filter and a second color filter arranged in each of the two sub-pixels, and
wherein the first color filter is partially overlapped with the second color filter under the bank.

9. The display apparatus of claim 7, wherein the substrate includes a pixel power line that supplies a driving voltage to each of the plurality of subpixels and the pixel power line overlaps the bank.

10. The display apparatus of claim 9, wherein a width of the bank is wider than a width of the pixel power line.

11. The display apparatus of claim 5, wherein a thickness of the second layer is thicker than a thickness of the first layer.

12. The display apparatus of claim 11, wherein a second capacitance of the second capacitor is greater than a first capacitance of the first capacitor.

13. The display apparatus of claim 5, wherein the pixel electrode comprises:
a concave portion sunk in a direction from the counter electrode toward the substrate; and
a flat portion arranged farther away from the substrate than the concave portion, and
wherein a width of the concave portion is equal to or smaller than a width of the second layer.

14. The display apparatus of claim 13, wherein a third capacitance formed between the flat portion and the first layer is smaller than a fourth capacitance formed between the concave portion and the second layer.

15. The display apparatus of claim 13, wherein the organic light-emitting layer is disposed along a profile of the concave portion and the flat portion.

16. The display apparatus of claim 13, further comprising:
an overcoat layer between the pixel electrode and the color filter layer, the overcoat layer including:
a first overcoat layer between the concave portion and the color filter layer; and
a second overcoat layer connected to the first overcoat layer and between the flat portion and the color filter layer, and
wherein a thickness of the first overcoat layer is thinner than a thickness of the second overcoat layer.

17. The display apparatus of claim 1, wherein each of the plurality of subpixels includes a light emission area where light is emitted, and
wherein the second layer overlaps with the light emission area of one of the plurality of subpixels.

18. The display apparatus of claim 1, wherein each of the plurality of subpixels includes a light emission area in which light is emitted,
wherein the light emission area includes a plurality of short sides and a plurality of long sides connected to the plurality of short sides, and
wherein the second layer extends along one long side of the plurality of long sides and is arranged adjacent to each of the plurality of short sides.

19. The display apparatus of claim 1, wherein each of the plurality of subpixels includes a light emission area in which light is emitted,
wherein the light emission area includes a plurality of short sides and a plurality of long sides connected to the plurality of short sides, and
wherein the second layer extends along one short side of the plurality of short sides and is arranged adjacent to each of the plurality of long sides.

20. The display apparatus of claim 1, wherein each of the plurality of subpixels includes a light emission area where light is emitted,
wherein the light emission area includes a plurality of short sides and a plurality of long sides connected to the plurality of short sides, and
wherein the second layer is arranged partially adjacent to one of the plurality of short sides and partially adjacent to one of the plurality of long sides.
